(19) United States
(12) Patent Application Publication
(10) Pub. No.: US 2014/0183520 A1
(43) Pub. Date: Jul. 3, 2014

(54) OXIDE THIN FILM TRANSISTOR STRUCTURE AND METHOD THEREOF

(71) Applicant: HANNSTAR DISPLAY CORPORATION, New Taipei city (TW)

(72) Inventor: Ming-Chieh CHANG, Hsinchu County (TW)

(73) Assignee: HannStar Display Corporation, New Taipei City (TW)

(21) Appl. No.: 13/864,227

(22) Filed: Apr. 16, 2013

(30) Foreign Application Priority Data
Dec. 31, 2012 (CN) 201210593030.9

(51) Int. Cl. H01L 29/786; H01L 29/66

(52) U.S. Cl. CPC H01L 29/7869; H01L 29/66969
USPC 257/43; 438/104

(57) ABSTRACT

An oxide thin film transistor structure includes a substrate, a drain electrode disposed on the substrate, and a first insulation layer disposed on the drain electrode and the substrate. The first insulation layer has a first opening to expose a part of the drain electrode. A gate electrode and a gate insulation layer are sequentially disposed on the first insulation layer and located around the first opening. A metal oxide channel layer is disposed on the gate insulation layer and located in the first opening. A source electrode is disposed on the metal oxide channel layer. An area of the metal oxide channel layer corresponding to the first opening is a channel region.

### RELATED APPLICATIONS

This application claims priority to Chinese Application Serial Number 201210593030.9 filed Dec. 31, 2012, which is herein incorporated by reference.

### TECHNICAL FIELD

The present disclosure relates to a transistor structure and method thereof, and more particularly to an oxide thin film transistor structure and method thereof.

### BACKGROUND

In recent years, flat panel displays have gradually replaced conventional cathode ray tube displays. Current flat panel displays include organic light-emitting diode (OLED) displays, plasma display panels (PDPs), liquid crystal displays (LCDs), field emission displays (FEDs), and some other less well-known display configurations. An essential component of these flat panel displays is the thin-film transistor (TFT), which controls the on and off state of each pixel.

Referring to FIG. 1, which schematically illustrates a cross-sectional view of a conventional oxide thin film transistor structure, the conventional oxide thin film transistor structure 100 includes a substrate 101, a gate electrode 102 disposed on the substrate 101, a semiconductor insulation layer 103 disposed on the substrate 101 and the gate electrode 102, a metal oxide layer 104 disposed on the semiconductor insulation layer 103, and a source electrode 105 and a drain electrode 106 each disposed on the metal oxide layer 104. The source electrode 105 and the drain electrode 106 are formed by performing an etching process on a metal layer. However, in the etching process for forming the source electrode 105 and the drain electrode 106 of the conventional oxide thin film transistor structure 100, the metal oxide layer 104 disposed below the source electrode 105 and the drain electrode 106 tends to be corroded by the etching solution used in the process. Thus, a break may be formed in the metal oxide layer 104. Moreover, UV light used in the etching process also affects the electric properties of the metal oxide layer 104.

Therefore, there is a need for improving the quality and production yield of the oxide thin film transistor by preventing a metal etching solution from corroding the metal oxide layer while etching the source electrode and the drain electrode.

### SUMMARY

Accordingly, the present invention provides an oxide thin film transistor. The source electrode and the drain electrode are arranged in the perpendicular direction, the gate electrode is disposed on two sides, and the metal oxide channel layer is disposed in an opening, thereby preventing damage by a metal etching solution, hydrogen doping and UV light so that the quality and production yield of the oxide thin film transistor are improved.

The present invention discloses an oxide thin film transistor structure. The oxide thin film transistor including a substrate, a drain electrode disposed on the substrate, and a first insulation layer disposed on the drain electrode and the substrate. The first insulation layer has a first opening to expose a part of the drain electrode. A gate electrode and a gate insulation layer are sequentially disposed on the first insulation layer and located around the first opening. A metal oxide channel layer is disposed on the gate insulation layer and located in the first opening. A source electrode is disposed on the metal oxide channel layer. An area of the metal oxide channel layer corresponding to the first opening is a channel region.

In an embodiment, the oxide thin film transistor structure further comprises a second insulation layer disposed on the source electrode and the gate insulation layer, and a pixel electrode layer disposed on the second insulation layer and located in the second opening. The second insulation layer has a second opening to expose a part of the source electrode.

In an embodiment, the first insulation layer is made of a material including silicon nitride (SiNx), silicon oxide (SiOx), silicon oxide nitride (SiOxNx), alumina (AlOx), or Titanium oxide (TiOx).

In an embodiment, the second insulation layer is made of a material including silicon nitride (SiNx), silicon oxide (SiOx), silicon oxide nitride (SiOxNx), alumina (AlOx), or Titanium oxide (TiOx).

In an embodiment, the gate insulation layer is made of a material including silicon nitride (SiNx), silicon oxide (SiOx), silicon oxide nitride (SiOxNx), alumina (AlOx), or Titanium oxide (TiOx).

In an embodiment, the metal oxide channel layer is made of a material including indium gallium zinc oxide (IGZO), indium zinc oxide (IZO), zinc oxide (IZO), amorphous silicon (a-Si), or poly-silicon (a-Si).

In an embodiment, the pixel electrode layer is made of a material including Indium Zinc Oxide (IZO), Indium Tin Oxide (ITO) or Zinc Oxide (ZnO).

The present invention also discloses a method for forming an oxide thin film transistor. The method comprises providing a substrate, forming a drain electrode on the substrate, and forming a first insulation layer on the drain electrode and the substrate. The first insulation layer has a first opening to expose a part of the drain electrode. Next, a gate electrode is formed on the first insulation layer and located around the first opening. A gate insulation layer is then formed on the gate electrode and located around the first opening. Subsequently, a metal oxide channel layer is formed on the gate insulation layer and located in the first opening, after which a source electrode is formed on the metal oxide channel layer. An area of the metal oxide channel layer corresponding to the first opening is a channel region.

In an embodiment, the method for forming an oxide thin film transistor further comprises forming a second insulation layer on the source electrode and the gate insulation layer, and forming a pixel electrode layer on the second insulation layer and located in the second opening. The second insulation layer has a second opening to expose a part of the source electrode.

With the above structure, the source electrode covers the metal oxide channel layer, thereby preventing the metal oxide layer from corroding by the metal etching solution while a wet etching process is performed on the metal layer. In addition, damage to the metal oxide layer by the hydrogen doping process when the insulation layer is formed, or by UV light when performing a photolithography and etching process can be prevented. Therefore, the quality and production yield of the oxide thin film transistor are improved.

### BRIEF DESCRIPTION OF THE DRAWINGS

In order to make the foregoing as well as other aspects, features, advantages, and embodiments of the present disclosure more apparent, the accompanying drawings are described as follows:

FIG. 1 illustrates a cross-sectional view of a conventional oxide thin film transistor structure.

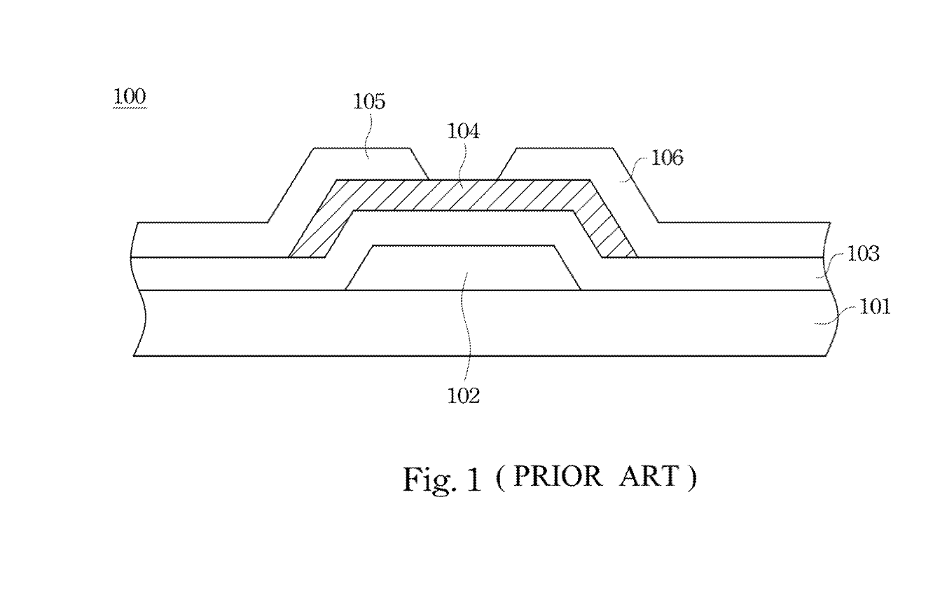

FIG. 2A illustrates a cross-sectional view taken along line A-A′ of FIG. 2B.

FIG. 2B illustrates a top view of a drain electrode on a substrate.

FIG. 3A illustrates a cross-sectional view taken along line A-A′ of FIG. 3B.

FIG. 3B illustrates a top view of a gate electrode on the drain electrode.

FIG. 4A illustrates a cross-sectional view taken along line A-A′ of FIG. 4B.

FIG. 4B illustrates a top view of a gate insulation layer on the gate electrode.

FIG. 5A illustrates a cross-sectional view taken along line A-A′ of FIG. 5B.

FIG. 5B illustrates a top view of a metal oxide channel layer on the gate insulation layer.

FIG. 6A illustrates a cross-sectional view taken along line A-A′ of FIG. 6B.

FIG. 6B illustrates a top view of a source electrode on the metal oxide channel layer gate.

FIG. 7A illustrates a cross-sectional view taken along line A-A′ of FIG. 7B.

FIG. 7B illustrates a top view of a second insulation layer on the source electrode.

FIG. 8A illustrates cross-sectional view taken along line A-A′ of FIG. 8B.

FIG. 8B illustrates a top view of a pixel electrode on the second insulation layer.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

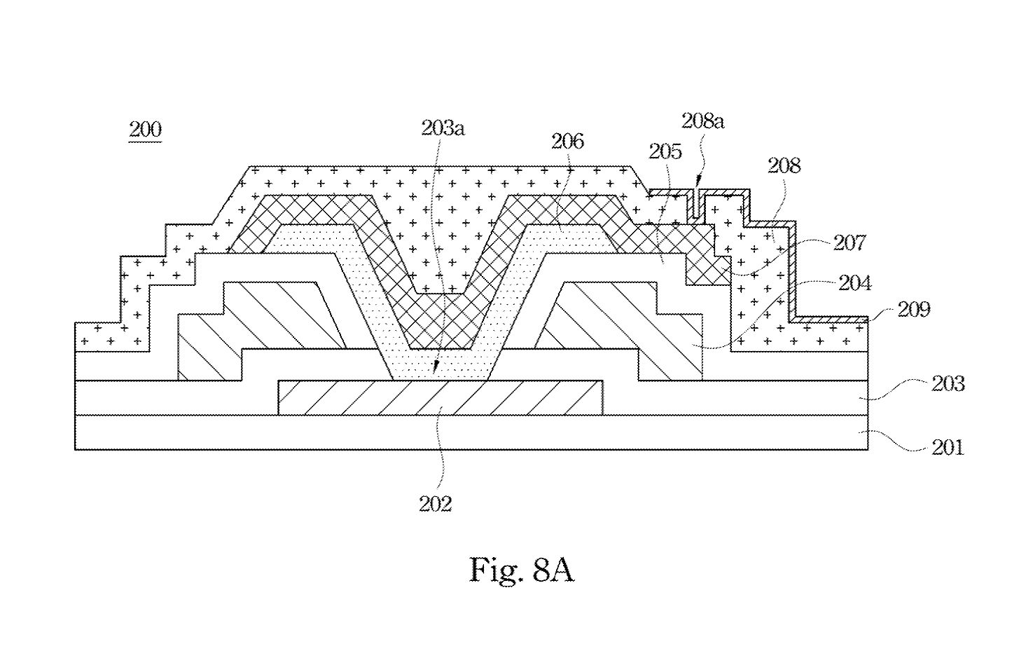

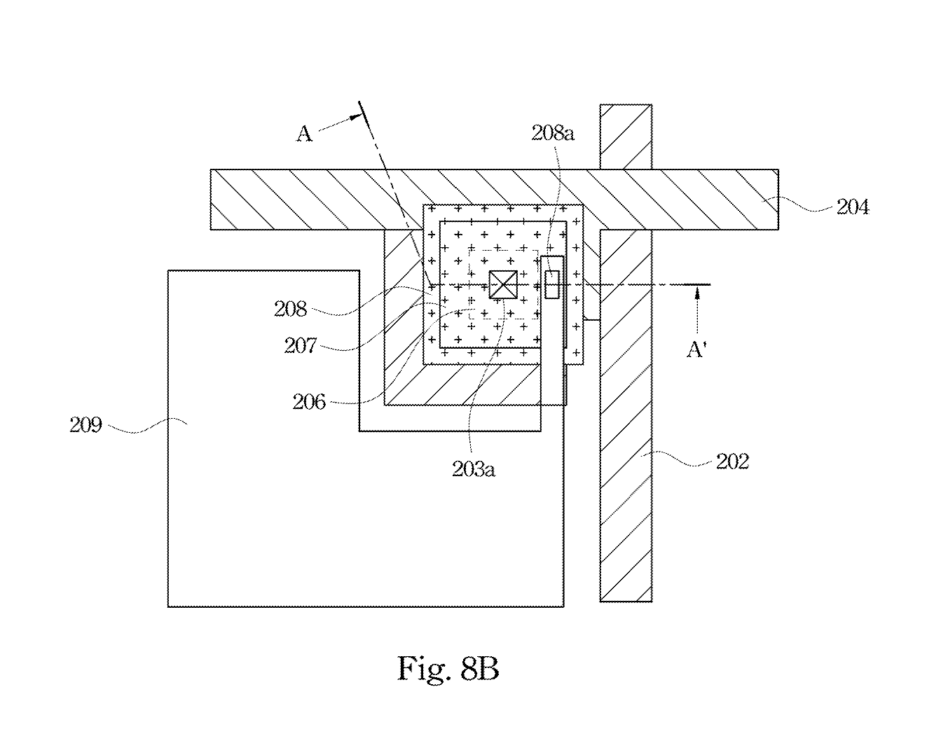

Reference is first made to FIG. 8A which schematically illustrates a cross-sectional view of an oxide thin film transistor structure according to an embodiment of the present invention. As shown in FIG. 8A, the oxide thin film transistor structure 200 includes a substrate 201. A drain electrode 202 is disposed on the substrate 201. A first insulation layer 203 is disposed on the substrate 201 and the drain electrode 202. An opening 203a is formed in the first insulation layer 203 to expose part of the drain electrode 202. A gate electrode 204 and a gate insulation layer 205 are sequentially disposed on the first insulation layer 203 and around the opening 203a. A metal oxide channel layer 206 is disposed on the gate insulation layer 205 and in the opening 203a. A source electrode 207 is disposed on the metal oxide channel layer 206. An area of the metal oxide channel layer 206 corresponding to the opening 203a is a channel region. A second insulation layer 208 is disposed on the source electrode 207 and the gate insulation layer 205. An opening 208a is formed in the second insulation layer 208 to expose part of the source electrode 207. A pixel electrode layer 209 is disposed on the second insulation layer 208 and in the opening 208a.

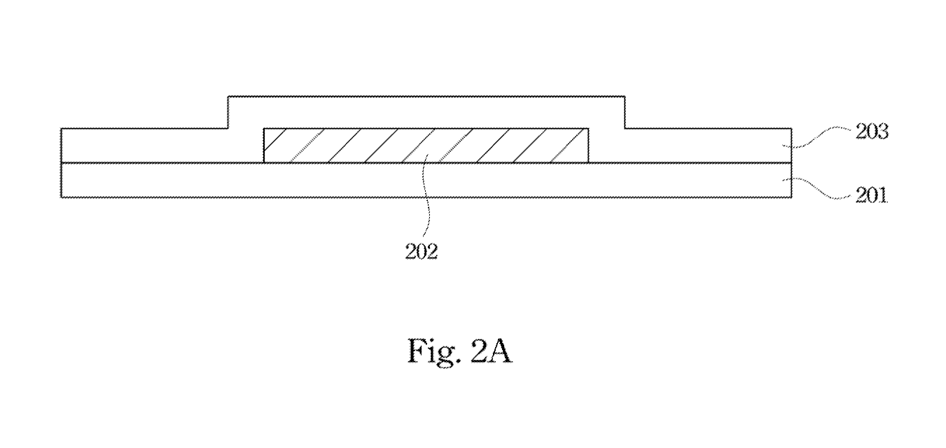

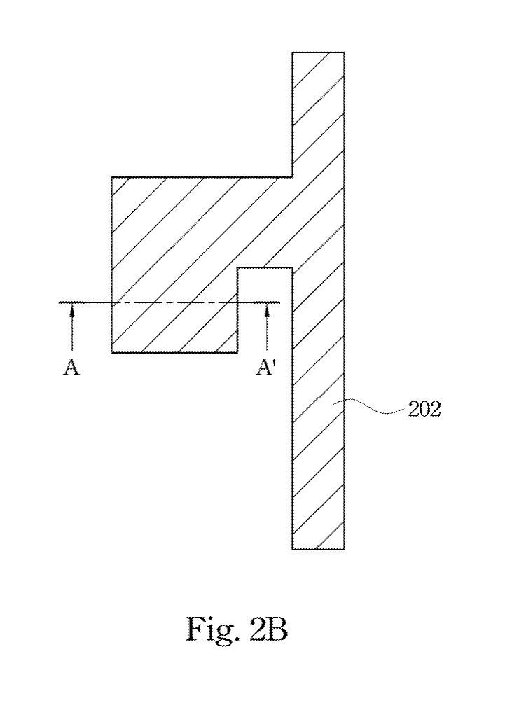

Reference is now made to FIG. 2A through FIG. 8B which schematically illustrate a method of forming the oxide thin film transistor structure according to an embodiment of the present invention.

FIG. 2A illustrates a cross-sectional view taken along line A-A′ of FIG. 2B. FIG. 2B illustrates a top view of a drain electrode on a substrate. As shown in FIG. 2A and FIG. 2B, a substrate 201 is provided. Subsequently, a first metal layer is formed on the substrate 201, and a drain electrode 202 is formed by, for instance, performing a photolithography and etching process on the first metal layer. A first insulation layer 203 is formed on the substrate 201 and the drain electrode 202. In an embodiment, the drain electrode 202 is made of an material including Aluminum (Al), Molybdenum (Mo), Titanium (Ti), Chromium (Cr), Copper (Cu), Gold (Au), Silver (Ag), or AlNd or an alloy or compound thereof, but is not limited in this regard. The first insulation layer 203 is made of a material including silicon nitride (SiNx), silicon oxide (SiOx), silicon oxide nitride (SiOxNx), alumina (AlOx), or Titanium oxide (TiOx), but the first insulation layer 203 is not limited in this regard.

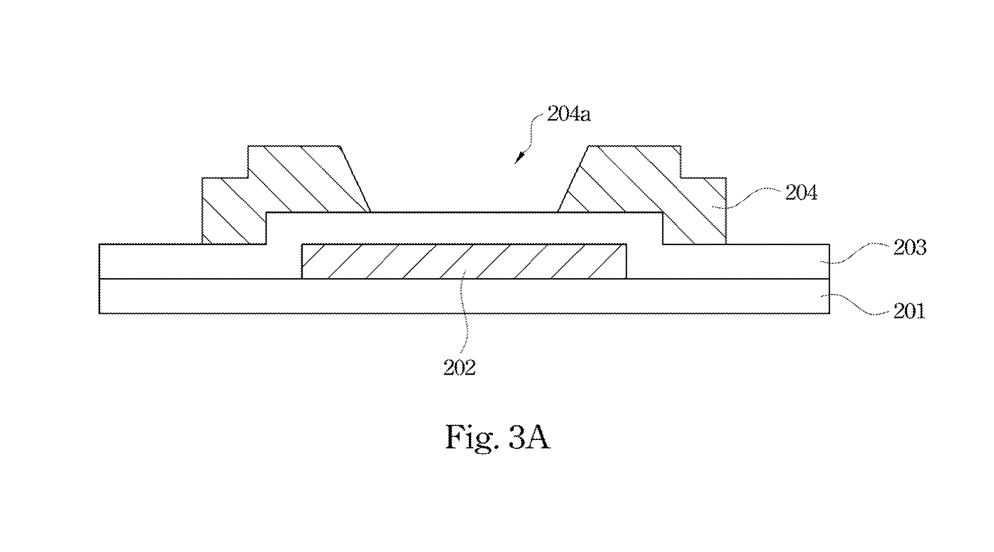

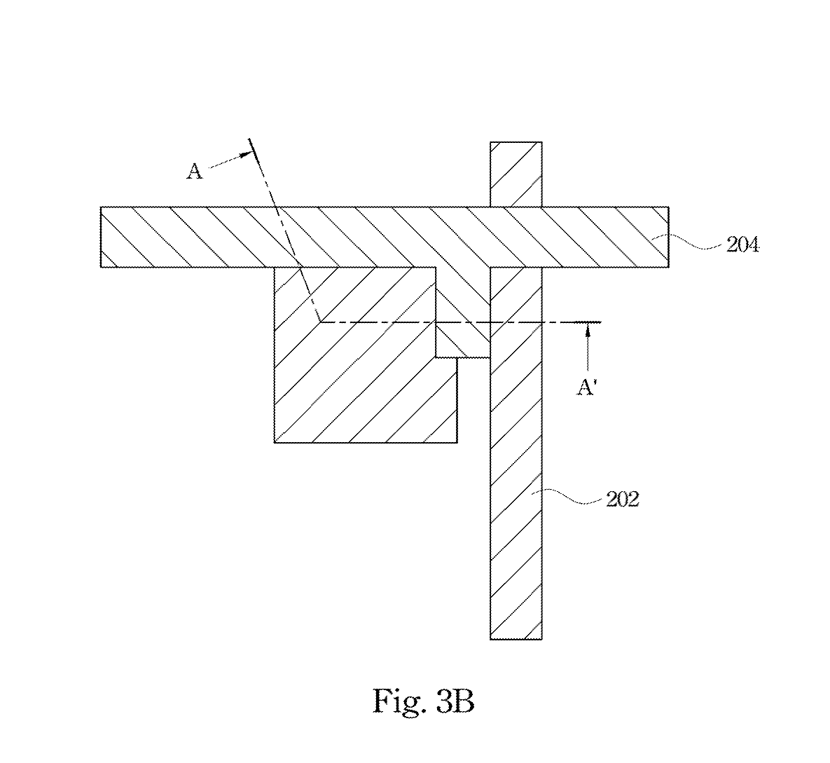

FIG. 3A illustrates a cross-sectional view taken along line A-A′ of FIG. 3B. FIG. 3B illustrates a top view of a gate electrode on the drain electrode. As shown in FIG. 3A and FIG. 3B, a second metal layer is formed on the first insulation layer 203. and a gate electrode 204 is formed by, for instance, performing a photolithography and etching process on the second metal layer. An opening 204a is formed in an area of the gate electrode 204 corresponding to the drain electrode 202 to expose part of the first insulation layer 203. The gate electrode 204 is formed on at least two sides of the drain electrode 202. In an embodiment, the gate electrode 204 can be made of a material including aluminum (Al), molybdenum (Mo), titanium (Ti), chromium (Cr), copper (Cu), Gold (Au), Silver (Ag), or AlNd, or an alloy or compound thereof, but is not limited in this regard.

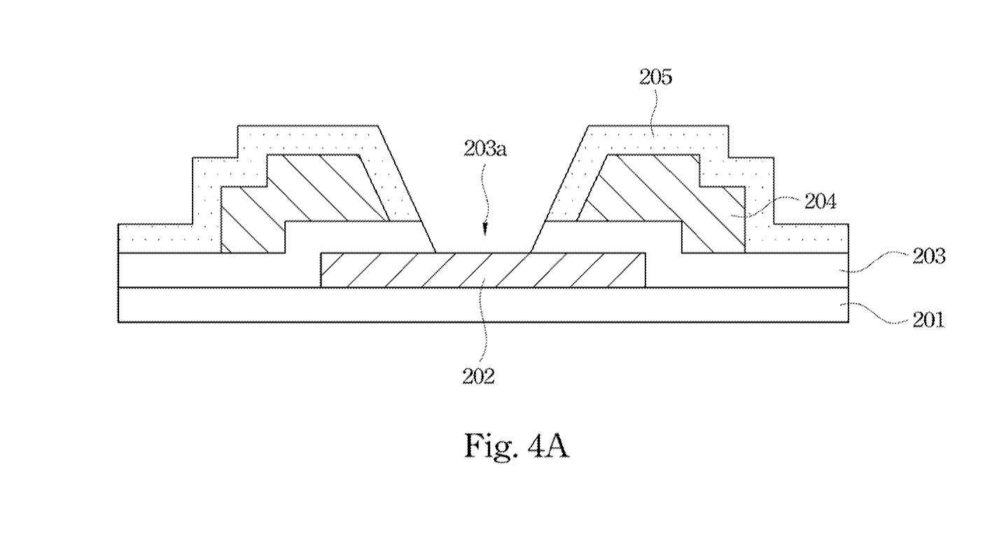

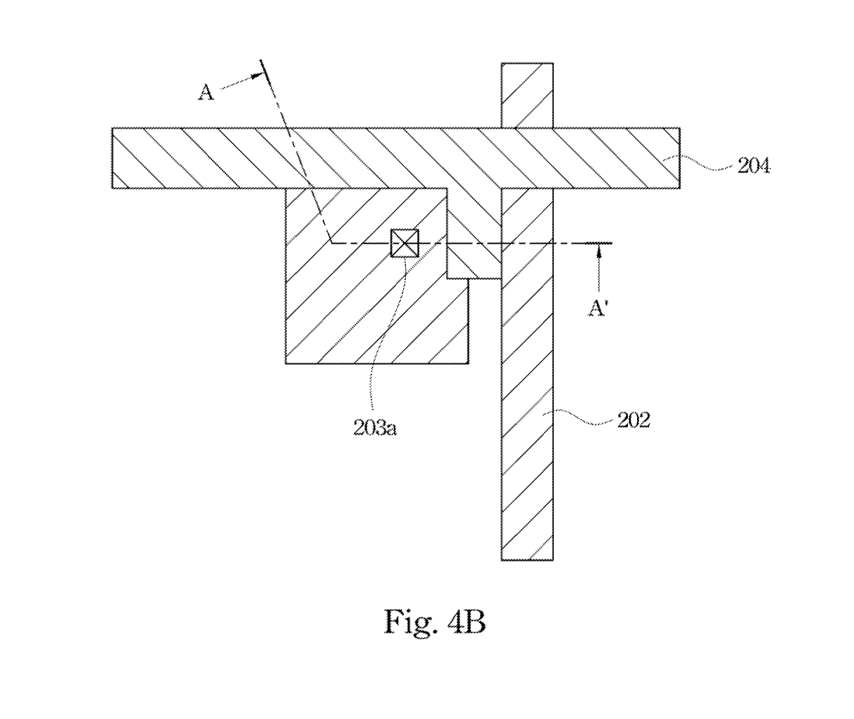

FIG. 4A illustrates a cross-sectional view taken along line A-A′ of FIG. 4B. FIG. 4B illustrates a top view of a gate insulation layer on the gate electrode. An insulation layer is formed on the gate electrode 204 and the first insulation layer 203. The insulation layer is filled into the opening 204a (see FIG. 3A). Subsequently, a gate insulation layer 205 is formed on the gate electrode 204 by, for instance, performing a photolithography and etching process on the insulation layer. Because the gate insulation 205 and the first insulation layer 203 are made by the same material, after the gate insulation 205 is removed from the opening 204a by etching, the exposed first insulation layer 203 is subsequently also etched to form an opening 203a to expose part of the drain electrode 202. In an embodiment, the gate insulation layer 205 is made of a material including silicon nitride (SiNx), silicon oxide (SiOx), silicon oxide nitride (SiOxNx), alumina (AlOx), or Titanium oxide (TiOx), but the first insulation layer 203 is not limited in this regard.

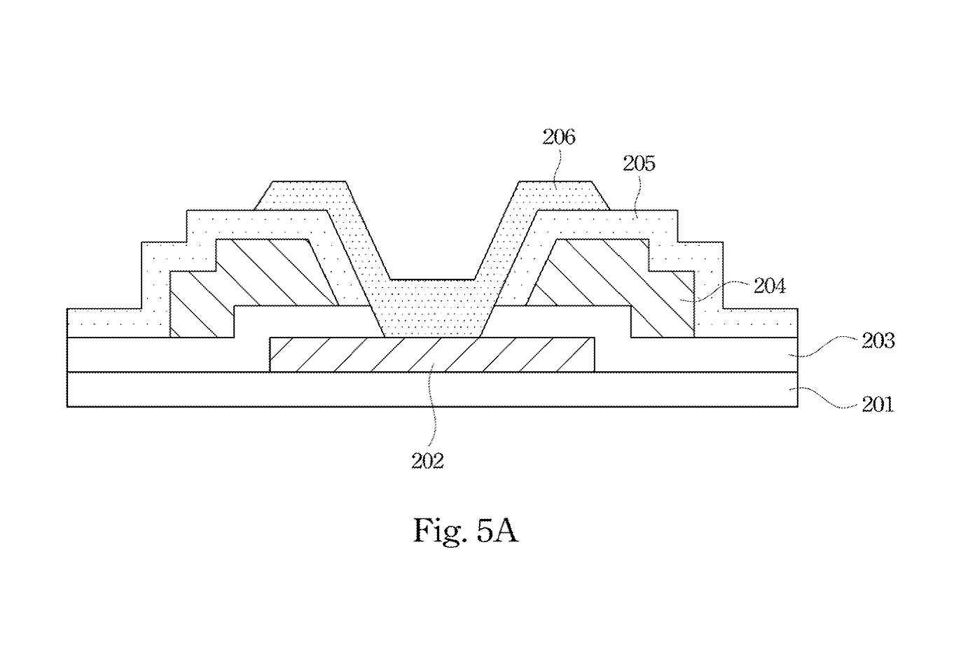

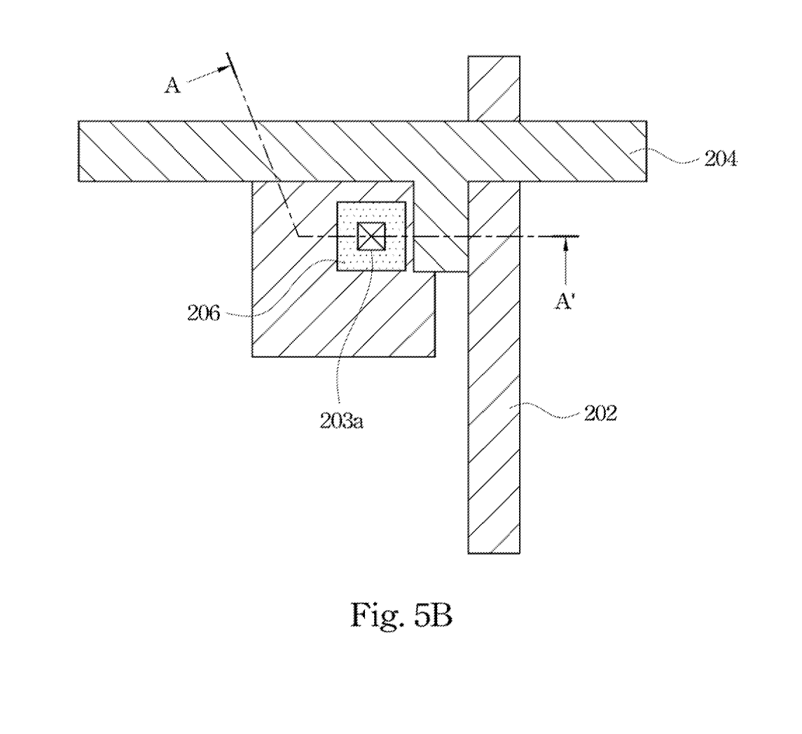

FIG. 5A illustrates a cross-sectional view taken along line A-A′ of FIG. 5B. FIG. 58 illustrates a top view of a metal oxide channel layer on the gate insulation layer. A metal oxide layer is formed on the gate insulation layer 205 and filled into the opening 203a (see FIG. 4A). Subsequently, a metal oxide channel layer 206 is formed on the gate insulation layer 205 and the opening 203a by, for instance, performing a photolithography and etching process on the metal oxide layer. An area of the metal oxide channel layer 206 corresponding to the opening 203a is a channel region. Moreover, because the size of the opening 203a is related to the thickness of the gate electrode 204, the gate insulation layer 205 and the first insulation layer 203, the length of the channel region is defined by the thickness of the gate electrode 204, the gate insulation layer 205 and the first insulation layer 203. That is, the photolithography and etching process does not limit the channel length. In an embodiment, the metal oxide channel layer 206 is made of an oxide material including indium gallium zinc oxide (IGZO), indium zinc oxide (IZO), zinc oxide (IZO), amorphous silicon (a-Si), or poly-silicon (a-Si), but is not limited in this regard. In this embodiment, the metal oxide layer is deposited on the gate insulation layer 205 by performing a vacuum sputtering process, but the metal oxide layer is not limited to being formed by such deposition. The metal oxide layer also can be formed on the gate insulation layer 205 by, for example, coating a liquid, or by other processes.

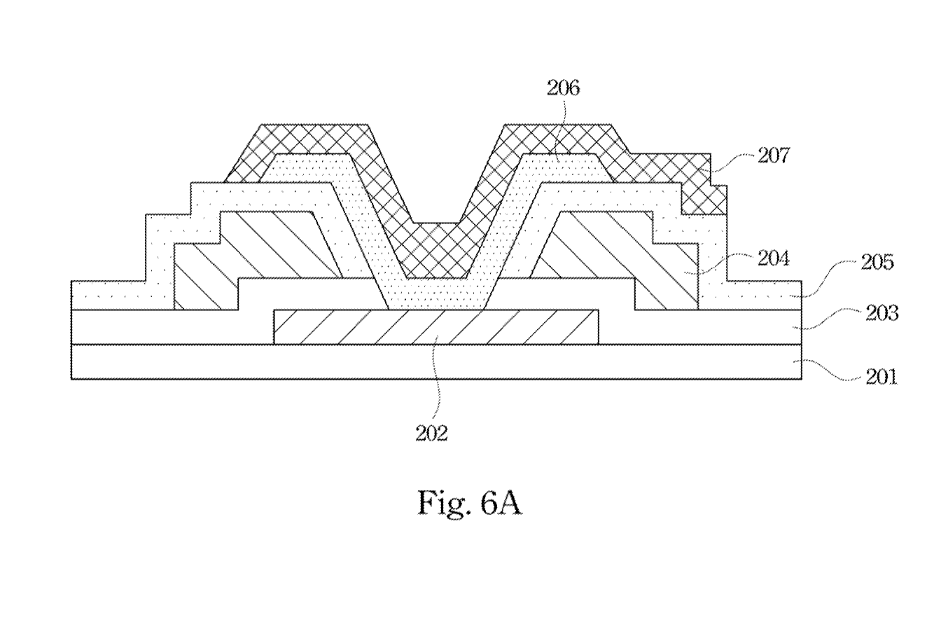

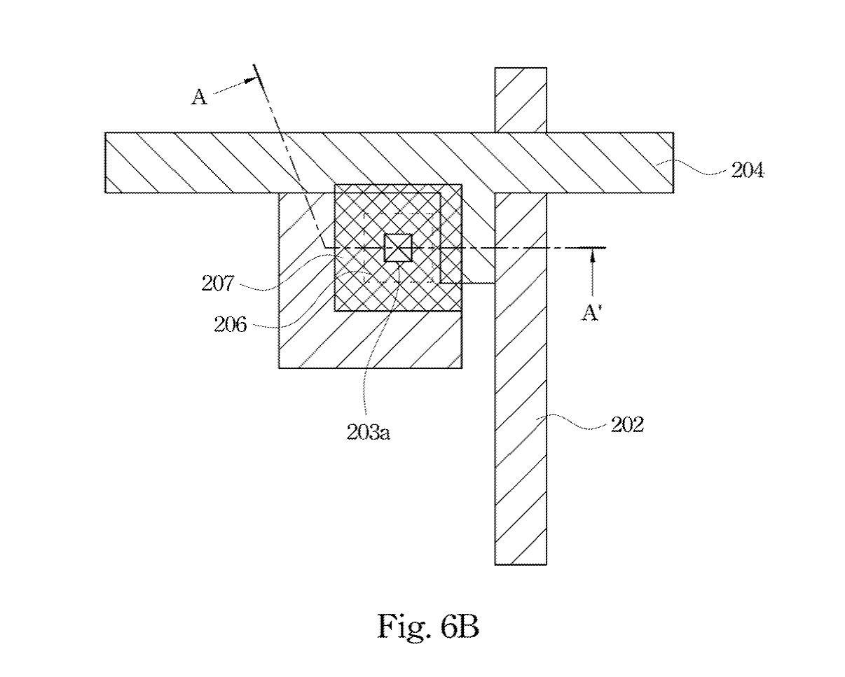

FIG. 6A illustrates a cross-sectional view, taken along line A-A′ of FIG. 6B. FIG. 6B illustrates a top view of a source electrode on the metal oxide channel layer gate. A second metal layer is formed on the metal oxide channel layer 206 and the gate insulation layer 205. Subsequently, a source electrode 207 is formed on the metal oxide channel layer 206 and the gate insulation layer 205 by, for instance, performing a photolithography and etching process on the metal oxide layer. In an embodiment, the source electrode 207 can be made of a material including aluminum (Al), molybdenum (Mo), titanium (Ti), chromium (Cr), copper (Cu), Gold (Au), Silver (Ag), or AlNd, or an alloy or compound thereof, but is not limited in this regard.

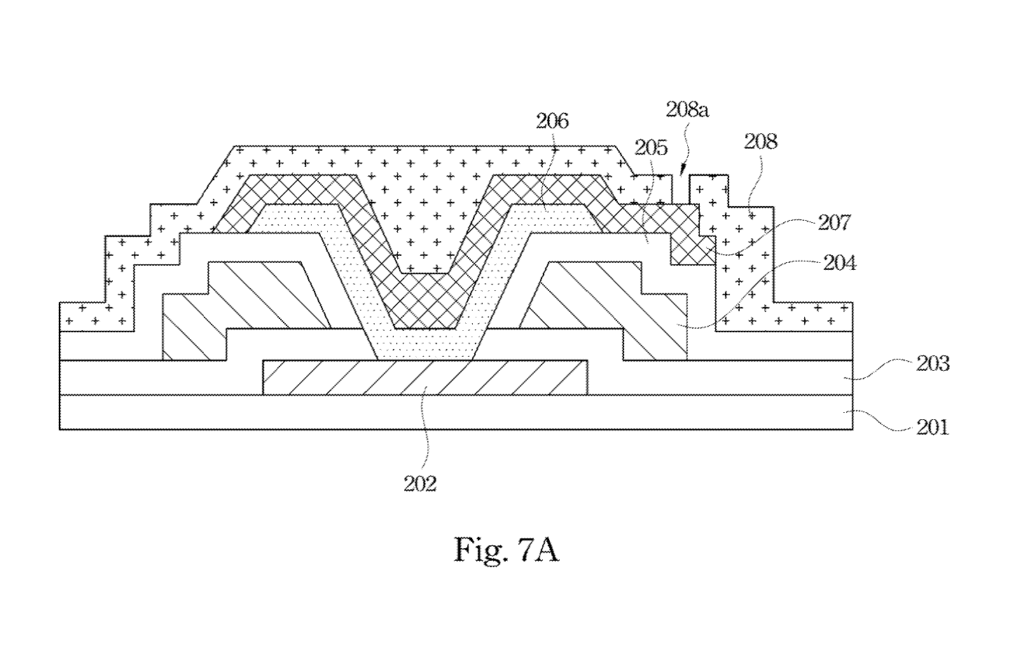

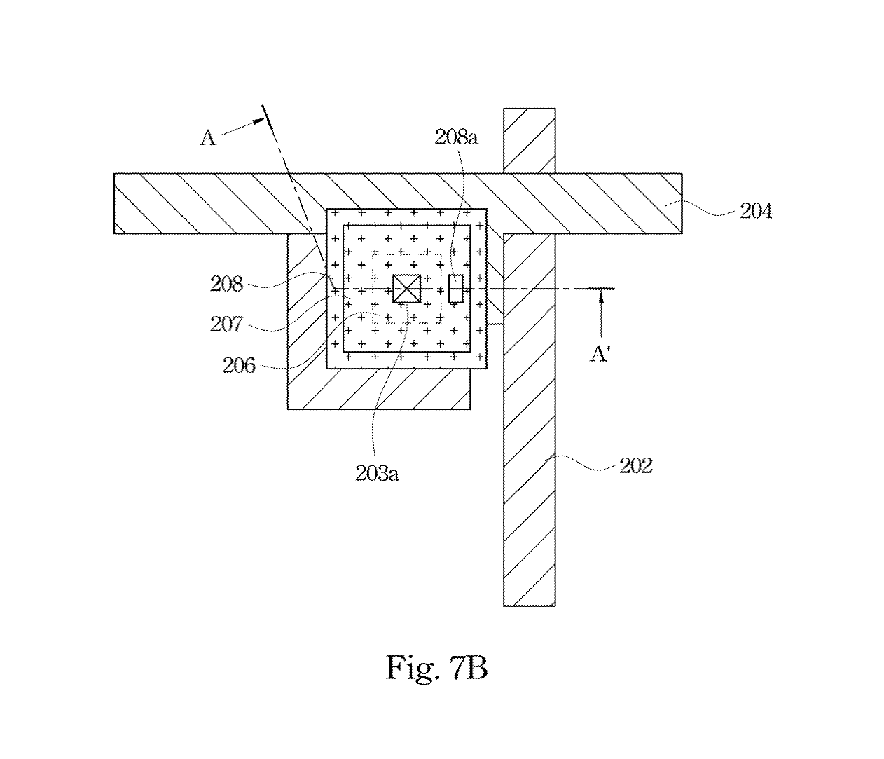

FIG. 7A illustrates a cross-sectional view taken along line A-A′ of FIG. 7B. FIG. 7B illustrates a top view of a second insulation layer on the source electrode. A second insulation layer 208 is formed on the source electrode 207 and the gate insulation layer 205. Subsequently, an opening 208a is formed in an area in the second insulation layer 208 corresponding to the source electrode 207 to expose part of the source electrode 207 by, for instance, performing a photolithography and etching process on the second insulation layer 208. The opening 208a is used to couple with a pixel electrode. The fabricating process of the second insulation layer 208 involves hydrogen doping. However, if hydrogen doping is performed with respect to the metal oxide channel layer 206, the metal oxide channel layer 206 will become a conductive layer, which will result in the transistor failing. Therefore, in the embodiment, the source electrode 207 covers the area of the metal oxide channel layer 206 to prevent hydrogen doping of the metal oxide channel layer 206. Furthermore, the source electrode 207 covering the area of the metal oxide channel layer 206 also can prevent UV light from being irradiated onto the metal oxide channel layer 206 during the photolithography and etching process, and thereby adversely affecting the electric properties of the metal oxide channel layer 206. In an embodiment, the second insulation layer 208 is made of a material including silicon nitride (SiNx), silicon oxide (SiOx), silicon oxide nitride (SiOxNx), alumina (AlOx) or Titanium oxide (TiOx), but the first insulation layer 203 is not limited in this regard.

FIG. 8A illustrates a cross-sectional view taken along line A-A′ of FIG. 8B FIG. 8B illustrates a top view of a pixel electrode on the second insulation layer. A transparent electrode is formed on the second insulation layer 208 and the opening 208a. Subsequently, a pixel electrode 209 is formed on the second insulation layer 208 by, for instance, performing a photolithography and etching process on the transparent electrode. In an embodiment, the material of the pixel electrode 209 is made of an Indium Zinc Oxide (IZO), Indium Tin Oxide (ITO) or Zinc Oxide (ZnO) transparent conductive film, but the pixel electrode 209 is not limited in this regard.

Accordingly, the source electrode and the drain electrode are arranged in a perpendicular direction, the gate electrode is disposed on two sides of the source electrode and the drain electrode, and the metal oxide channel layer is disposed in the opening, thereby preventing the metal etching solution from corroding the metal oxide channel layer while a wet etching process is performed on the metal layer. Moreover, the source electrode covers the area of the metal oxide channel layer to thereby prevent hydrogen doping of the metal oxide channel layer and also prevent UV light from irradiating onto the metal oxide channel layer so that the electrical properties of the metal oxide channel layer are not adversely affected.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An oxide thin film transistor structure, comprising:
a substrate;
a drain electrode disposed on the substrate;
a first insulation layer disposed on the drain electrode and the substrate, wherein the first insulation layer has a first opening to expose a part of the drain electrode;
a gate electrode disposed on the first insulation layer and located around the first opening;
a gate insulation layer disposed on the gate electrode and located around the first opening;
a metal oxide channel layer disposed on the gate insulation layer and located in the first opening; and
a source electrode disposed on the metal oxide channel layer, wherein an area of the metal oxide channel layer corresponding to the first opening is a channel region.

2. The oxide thin film transistor structure of claim 1, further comprising:
a second insulation layer disposed on the source electrode and the gate insulation layer, wherein the second insulation layer has a second opening to expose a part of the source electrode; and
a pixel electrode layer disposed on the second insulation layer and located in the second opening.

3. The oxide thin film transistor structure of claim 2, wherein the first insulation layer is made of a material including silicon nitride (SiNx), silicon oxide (SiOx), silicon oxide nitride (SiOxNx), alumina (AlOx), or Titanium oxide (TiOx).

4. The oxide thin film transistor structure of claim 2, wherein the second insulation layer is made of a material including silicon nitride (SiNx), silicon oxide (SiOx), silicon oxide nitride (SiOxNx), alumina (AlOx), or Titanium oxide (TiOx).

5. The oxide thin film transistor structure of claim 2, wherein the gate insulation layer is made of a material including silicon nitride (SiNx), silicon oxide (SiOx), silicon oxide nitride (SiOxNx), alumina (AlOx) or Titanium oxide (TiOx).

6. The oxide thin film transistor structure of claim 2, wherein the metal oxide channel layer is made of a material including indium gallium zinc oxide (IGZO), indium zinc oxide (IZO), zinc oxide (IZO), amorphous silicon (a-Si), or poly-silicon (a-Si).

7. The oxide thin film transistor structure of claim 2, wherein the pixel electrode layer is made of a material including Indium Zinc Oxide (IZO), Indium Tin Oxide (ITO) or Zinc Oxide (ZnO).

8. A method for forming an oxide thin film transistor, comprising:
providing a substrate;
forming a drain electrode on the substrate;
forming a first insulation layer on the drain electrode and the substrate, wherein the first insulation layer has a first opening to expose a part of the drain electrode;
forming a gate electrode on the first insulation layer and located around the first opening;
forming a gate insulation layer on the gate electrode and located around the first opening;
forming a metal oxide channel layer on the gate insulation layer and located in the first opening; and
forming a source electrode on the metal oxide channel layer, wherein an area of the metal oxide channel layer corresponding to the first opening is a channel region.

9. The method of claim 1, further comprising:
forming a second insulation layer on the source electrode and the gate insulation layer, wherein the second insulation layer has a second opening to expose a part of the source electrode; and
forming a pixel electrode layer on the second insulation layer and located in the second opening.
